(19) United States
(12) Patent Application Publication
(10) Pub. No.: US 2026/0271517 A1
(43) Pub. Date: Sep. 10, 2026

(54) DISPLAY DEVICE

(71) Applicant: Sharp Display Technoloy Corporation, Kameyama City, Mie (JP)

(72) Inventors: Takao SAITOH, Kameyama City, Mie (JP); Yohsuke Kanzaki, Kameyama City, Mie (JP); Masaki Yamanaka, Kameyama City, Mie (JP); Mashiko Miwa, Kameyama City, Mie (JP); Yi Sun, Kameyama City, Mie (JP); Masaki Fujiwara, Kameyama City, Mie (JP)

(21) Appl. No.: 19/113,530

(22) PCT Filed: Sep. 21, 2022
(86) PCT No.: PCT/JP2022/035233

§ 371 Date: Mar. 20, 2025

(51) Int. Cl. H10K 59/121; H10K 59/131

(52) U.S. Cl. CPC H10K 59/1213; H10K 59/131

(57) ABSTRACT

A camera is disposed on a back face side of a substrate layer of an organic EL display device. A display region includes a second display region configured to transmit light toward the camera, inside a first display region. A plurality of TFTs in a TFT layer include an oxide semiconductor TFT. In the second display region, there are provided a first connection line and a second connection line for connecting an organic EL element and a pixel circuit. The first and second connection lines have optical transparency and are formed in different layers from each other. The second connection line is formed in the same layer as the layer of a semiconductor layer of the oxide semiconductor TFT, and is constituted by converting an oxide semiconductor into a conductor.

### TECHNICAL FIELD

The disclosure relates to a display device.

### BACKGROUND ART

In recent years, organic electro luminescence (hereinafter, referred to as EL) display devices using organic EL elements have been used in practical applications. In a case where the organic EL display device is used as a display of an information terminal such as a smartphone or a tablet terminal, or in a case where the organic EL display device is used as a display for performing bidirectional communication such as a video telephone call or a video conference, the organic EL display device is combined with a camera that captures an image on the front face side where the captured image is displayed, that is, combined with a so-called in-camera.

In such an organic EL display device provided with an in-camera, it is proposed to dispose a camera on the back face side of the organic EL display device at a position overlapping a display region in a plan view. An example of the organic EL display device discussed above is disclosed in PTL 1.

### CITATION LIST

### Patent Literature

PTL 1: JP 2022-041886 A

### SUMMARY OF INVENTION

### Technical Problem

In an organic EL display device provided with an in-camera, wiring lines for connecting organic EL elements and pixel circuits are provided in a portion of a display region through which external light to be utilized by the camera is transmitted. As the wiring lines for such connection, it is conceivable to form a first connection line electrically connected to the organic EL element and a second connection line electrically connecting the first connection line and the pixel circuit in different layers from each other in such a manner that the first connection line and the second connection line can be disposed to extend while intersecting each other in a plan view.

However, in a case where the above configuration is adopted, it is necessary to provide an interlayer insulating film between the first connection line and the second connection line. In addition, it is preferable that both the first connection line and the second connection line have optical transparency in order to raise transmittance of light to be utilized by the camera in the display region. Due to this, the first connection line and the second connection line cannot be formed together with the same layer as that of other wiring lines made of a metal material, and therefore are formed separately from the other wiring lines having light blocking characteristics. This leads to an increase in the number of layers constituting the organic EL display device.

An object of the disclosure is to raise transmittance of light to be utilized by an electronic component in a display region of a display device, and reduce the number of layers of the display device.

### Solution to Problem

The disclosure is intended to be applied to a display device. The display device according to the disclosure includes a substrate, a thin film transistor layer provided on the substrate, and a light-emitting element layer provided on the thin film transistor layer. The thin film transistor layer includes a plurality of thin film transistors, and the light-emitting element layer includes a plurality of light-emitting elements corresponding to a plurality of subpixels forming a display region. On a back face side of the substrate, an electronic component configured to utilize light is disposed at a position overlapping the display region in a plan view. The display region includes a first display region and a second display region that is provided inside the first display region and transmits light to be utilized by the electronic component. The plurality of thin film transistors include a first thin film transistor including a semiconductor layer formed of an oxide semiconductor. In the second display region, a plurality of first connection lines electrically connected to the plurality of light-emitting elements and a plurality of second connection lines electrically connecting the plurality of first connection lines and the plurality of thin film transistors are provided. The first connection line and the second connection line have optical transparency and are formed in different layers from each other. The second connection line is formed in the same layer as the layer of the semiconductor layer of the first thin film transistor, and is constituted of a conductor layer obtained by converting the oxide semiconductor into a conductor.

### Advantageous Effects of Invention

With the display device according to the disclosure, an increase in transmittance of light to be utilized by an electronic component in a display region and a reduction in the number of layers of the display device can be achieved.

### BRIEF DESCRIPTION OF DRAWINGS

FIG. 1 is a plan view illustrating a schematic configuration of an organic EL display device.

FIG. 2 is a cross-sectional view of the organic EL display device taken along a line II-II in FIG. 1.

FIG. 3 is a plan view illustrating pixels and various wiring lines constituting a first display region of the organic EL display device.

FIG. 4 is a cross-sectional view of the first display region of the organic EL display device taken along a line IV-IV in FIG. 3.

FIG. 5 illustrates a cross-sectional view of an oxide semiconductor TFT (left drawing) and a cross-sectional view of a polysilicon TFT (right drawing).

FIG. 6 is an equivalent circuit diagram illustrating an example of a pixel circuit.

FIG. 7 is a plan view illustrating an example of a schematic configuration of a second display region and its periphery of the organic EL display device.

FIG. 8 is a plan view illustrating a main portion of the organic EL display device circled by a line VIII in FIG. 7.

FIG. 9 is a cross-sectional view of the main portion taken along a line IXa-IXa in FIG. 8 (left drawing) and a cross-sectional view of the main portion taken along a line IXb-IXb in FIG. 8 (right drawing).

FIG. 10 is a cross-sectional view illustrating a part of a manufacturing process of an organic EL display device.

FIG. 11 is a cross-sectional view illustrating a part of the manufacturing process of the organic EL display device.

FIG. 12 is a cross-sectional view illustrating a part of the manufacturing process of the organic EL display device.

FIG. 13 is a cross-sectional view illustrating a part of the manufacturing process of the organic EL display device.

FIG. 14 is a cross-sectional view illustrating a part of the manufacturing process of the organic EL display device.

FIG. 15 is a cross-sectional view illustrating a part of the manufacturing process of the organic EL display device.

FIG. 16 is a cross-sectional view illustrating a part of the manufacturing process of the organic EL display device.

FIG. 17 is a cross-sectional view illustrating a part of the manufacturing process of the organic EL display device.

FIG. 18 is a cross-sectional view illustrating a part of the manufacturing process of the organic EL display device.

FIG. 19 is a cross-sectional view illustrating a part of the manufacturing process of the organic EL display device.

FIG. 20 is a cross-sectional view illustrating a part of the manufacturing process of the organic EL display device.

FIG. 21 is a cross-sectional view illustrating a part of the manufacturing process of the organic EL display device.

FIG. 22 is a cross-sectional view illustrating a part of the manufacturing process of the organic EL display device.

FIG. 23 is a cross-sectional view illustrating a part of the manufacturing process of the organic EL display device.

FIG. 24 is a cross-sectional view illustrating a part of the manufacturing process of the organic EL display device.

FIG. 25 is a cross-sectional view illustrating a part of the manufacturing process of the organic EL display device.

FIG. 26 is a cross-sectional view illustrating a part of the manufacturing process of the organic EL display device.

### DESCRIPTION OF EMBODIMENTS

Exemplary embodiments will be described below in detail with reference to the drawings. In the embodiments described below, an organic EL display device is described as an example of a display device according to the disclosure. Note that the drawings are for schematically describing the techniques of the disclosure. Thus, in the drawings, the dimensions, ratios, or numbers may be exaggerated or simplified to facilitate the techniques of the disclosure.

In the following embodiments, a “first direction” means a horizontal direction of a screen of a display device oriented in use. A “second direction” is a direction orthogonal to the first direction and means a vertical direction of the screen of the display device oriented in use. A row of constituent elements such as subpixels means a horizontal arrangement of a plurality of constituent elements forming a line in the first direction. A column of constituent elements such as subpixels means a vertical arrangement of a plurality of constituent elements forming a line in the second direction.

In the following embodiments, the description that, on a constituent element such as a certain film, layer or element, a constituent element such as another film, layer or element is provided or formed means not only a case where another constituent element is present immediately above the certain constituent element but also a case where a constituent element such as still another film, layer, or element is interposed between both the constituent elements.

In the following embodiments, the description that a certain constituent element is connected to another constituent element means that the constituent elements are electrically connected unless otherwise specified. This description means, without departing from the gist of the technique of the disclosure, not only a case where the constituent elements are directly connected but also a case where the constituent elements are indirectly connected with still another constituent element interposed therebetween. The description also includes a case where a certain constituent element is integrated with another constituent element, that is, a part of the certain constituent element constitutes the other constituent element.

In the following embodiments, a description that a certain constituent element and another constituent element are in the same layer means that the certain constituent element and the other constituent element are formed by the same process. A description that a certain constituent element is in a lower layer below another constituent element means that the certain constituent element is formed by a process earlier than that of the other constituent element. A description that a certain constituent element is in an upper layer above another constituent element means that the certain constituent element is formed by a process later than that of the other constituent element.

In the following embodiments, the description that a certain constituent element is the same as or equivalent to another constituent element includes not only a state where the certain constituent element is completely the same as or completely equivalent to the other constituent element, but also a state where the certain constituent element is substantially the same as or substantially equivalent to the other constituent element, such as a state where the certain constituent element and the other constituent element vary within a range of a manufacturing variation, tolerance, or the like.

In the following embodiments, the descriptions of first, second, third, . . . are used to distinguish the words and phrases to which these descriptions are given, and no limitation with regard to the number and order of the words and phrases is intended.

### Embodiments

An organic EL display device 1 of the present embodiment is used for mobile apparatuses such as a multifunctional telephone called a smartphone and a tablet terminal, and for various apparatuses such as a personal computer (PC) and a television set.

### Configuration of Organic EL Display Device

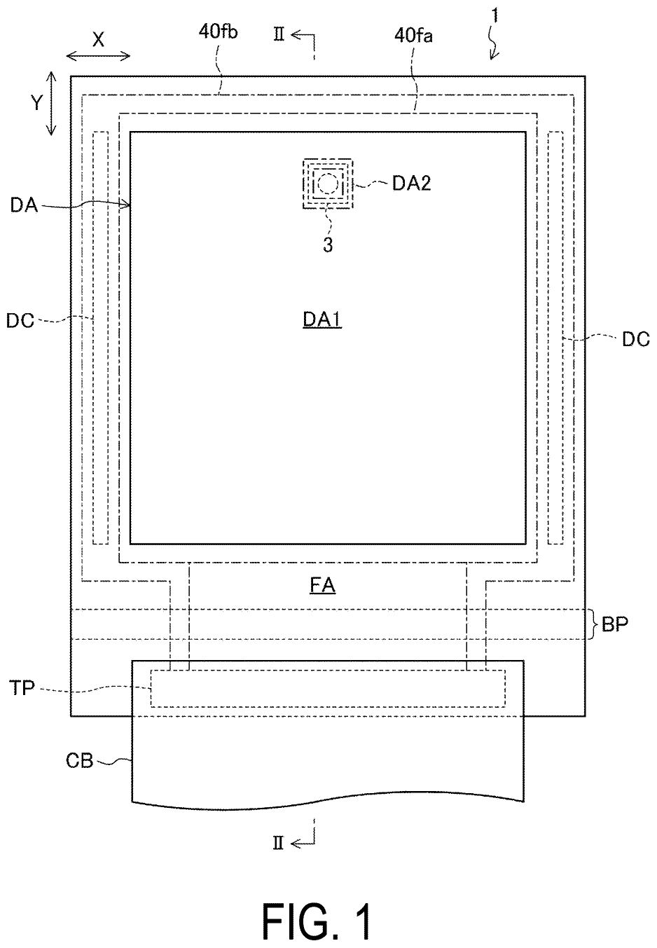

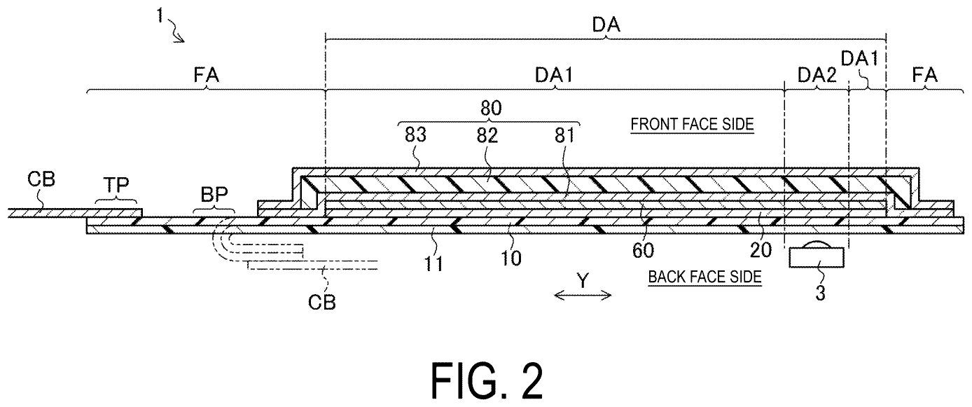

As illustrated in FIG. 1 and FIG. 2, the organic EL display device 1 constitutes a display device provided with an in-camera, which is achieved by being combined with a camera 3 for capturing an image on the front face side where the captured image is displayed. The organic EL display device 1 includes a display region DA and a frame region FA.

The display region DA is a region in which an image is displayed. The display region DA constitutes a screen. The display region DA is provided in a rectangular shape, for example. The display region DA may have a substantially rectangular shape such as a shape in which at least one side is arc-shaped, a shape in which at least one corner is arc-shaped or a shape in which a cutout portion is formed in at least one side, or may have any other shape.

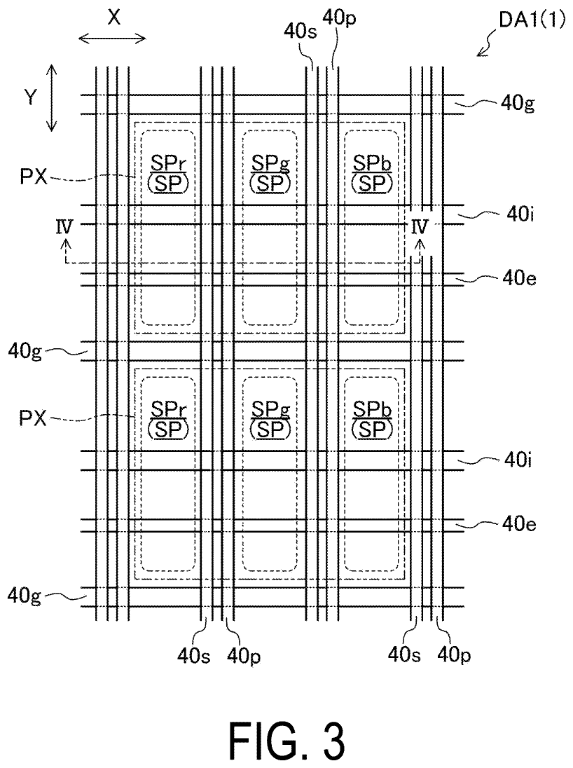

As illustrated in FIG. 3, the display region DA includes a plurality of pixels PX. The plurality of pixels PX are arrayed in a matrix shape. Each pixel PX is constituted by three subpixels SP. The three subpixels SP are a subpixel SPr for emitting red light, a subpixel SPg for emitting green light, and a subpixel SPb for emitting blue light. These three subpixels SPr, SPg, and SPb are arrayed in a stripe shape, for example.

As illustrated in FIGS. 1 and 2, the camera 3 is disposed at a position overlapping the display region DA in a plan view on the back face side of a substrate layer 10 of the organic EL display device 1. The camera 3 is an example of an electronic component that utilizes light. The camera 3 includes an image sensor of a charge coupled device (CCD) or a complementary metal oxide semiconductor (CMOS), for example. The camera 3 is installed inside a housing (not illustrated) that houses the organic EL display device 1.

The display region DA includes a first display region DA1 and a second display region DA2. The first display region DA1 is a region that occupies most of the display region DA. The second display region DA2 is provided inside the first display region DA1. The second display region DA2 is a region including a portion that transmits light to be utilized by the camera 3. The second display region DA2 is provided in a rectangular island shape at one side (upper side in FIG. 1) of the display region DA, for example. The second display region DA2 may have another shape such as a circular shape or an elliptical shape.

The frame region FA is a region that constitutes a non-display region other than the screen. The frame region FA is provided in a rectangular frame shape, for example. The frame region FA may have a frame shape other than the rectangular frame shape. The frame region FA includes a terminal portion TP and a bending portion BP. The terminal portion TP is a portion for connecting to an external circuit (such as a display control circuit). The terminal portion TP is provided at a position close to an outer edge of a portion constituting one side of the frame region FA in such a manner as to extend in a first direction X along the one side.

The bending portion BP is provided between the terminal portion TP in the frame region FA and the display region DA. The bending portion BP is a portion to be bent about a bending axis extending in the first direction X. The bending portion BP extends oblongly over the entire frame region FA in the first direction X. Although not illustrated, in the bending portion BP, an inorganic insulating film constituting a TFT layer 20 is removed to obtain higher flexibility than in other portions.

The frame region FA of the organic EL display device 1 is bent by, for example, about 180° so as to form a U shape at the bending portion BP (indicated by a two-dot chain line in FIG. 2). Thus, the terminal portion TP is disposed on the back face side of the organic EL display device 1. The terminal portion TP includes a plurality of terminals (not illustrated). To the terminal portion TP, a wiring line substrate CB such as a flexible printed circuit (FPC) is connected.

Drive circuits DC are provided in the frame region FA of the organic EL display device 1. In the frame region FA, the drive circuits DC are each disposed in a portion constituting a side (a left or right side in FIG. 1) adjacent to a side where the terminal portion TP is provided. The drive circuit DC is monolithically formed as a part of the TFT layer 20 described later. The drive circuit DC includes a gate driver and an emission driver.

In the frame region FA of the organic EL display device 1, there are provided a first frame line 40fa and a second frame line 40fb. The first frame line 40fa and the second frame line 40fb are each formed to surround the display region DA and extend to the terminal portion TP. A high-level power supply voltage (ELVDD) is supplied to the first frame line 40fa via the wiring line substrate CB. A low-level power supply voltage (ELVSS) is supplied to the second frame line 40fb via the wiring line substrate CB.

The organic EL display device 1 employs an active matrix driving method. In the organic EL display device 1, light emission from each of the subpixels SP is controlled by a thin film transistor (hereinafter referred to as a TFT) 50, so that image display is performed by operation of the TFT 50. As illustrated in FIG. 2, the organic EL display device 1 includes the substrate layer 10, the TFT layer 20, a light-emitting element layer 60, and a sealing film 80.

### Substrate Layer

The substrate layer 10 is a layer forming a base of the organic EL display device 1. The substrate layer 10 is an example of a substrate. The substrate layer 10 has both optical transparency (which refers to transparency of visible light; the same applies hereinafter) and flexibility. The substrate layer 10 is formed of an organic resin material such as a polyimide resin, a polyamide resin, or an epoxy resin. A protection film 11 having optical transparency is bonded to the back face of the substrate layer 10.

### TFT Layer

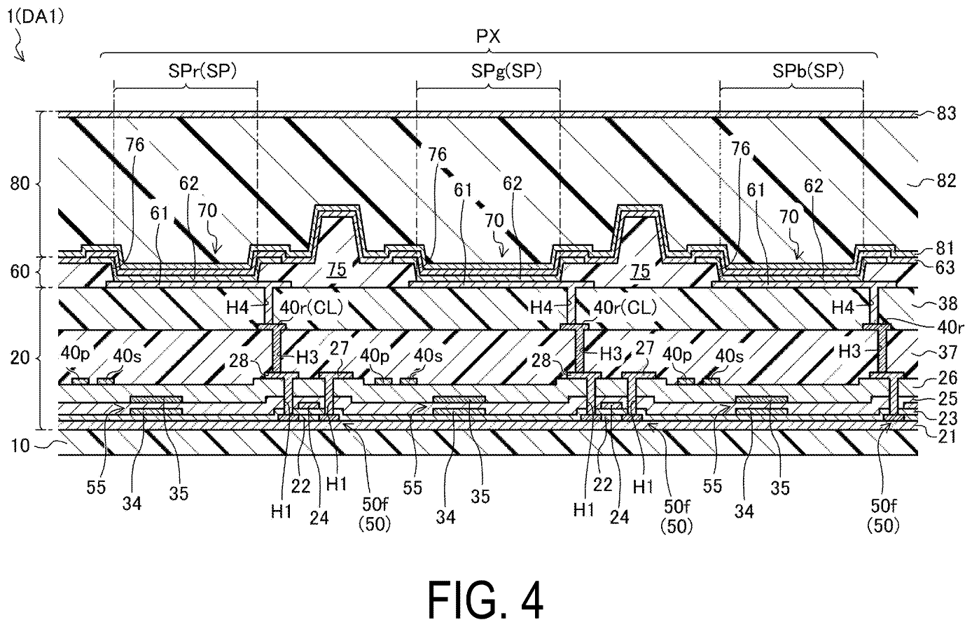

The TFT layer 20 is provided on the substrate layer 10. As illustrated in FIGS. 3 and 4, the TFT layer 20 includes, in addition to the above-described drive circuits DC, various wiring lines 40, a plurality of TFTs 50, and a plurality of capacitors 55. The various wiring lines 40, the plurality of TFTs 50, and the plurality of capacitors 55 are provided on a base coat film 21. The base coat film 21 is provided over the substantially entire surface of the substrate layer 10.

As the various wiring lines 40, in addition to the first frame line 40fa and the second frame line 40fb described above, a plurality of gate lines 40g, a plurality of light emission control lines 40e, a plurality of second initialization lines 40i, a plurality of power source lines 40p, and a plurality of source lines 40s are provided. The gate line 40g, the light emission control line 40e, and the second initialization line 40i are examples of a first metal line. The source line 40s and the power source line 40p are examples of a second metal line.

Each of the plurality of gate lines 40g is a wiring line that transmits a gate signal. The plurality of gate lines 40g are disposed at intervals between each other in a second direction Y in the display region DA, and extend in parallel to each other in the first direction X. The gate line 40g is provided for each row of the subpixels SP. Each of the gate lines 40g is connected to the gate driver of the drive circuit DC.

Each of the plurality of light emission control lines 40e is a wiring line that transmits an emission signal. The plurality of light emission control lines 40e are disposed at intervals between each other in the second direction Y in the display region DA, and extend in parallel to each other in the first direction X. The light emission control line 40e is provided for each row of the subpixels SP. Each of the light emission control lines 40e is connected to the emission driver of the drive circuit DC.

Each of the plurality of second initialization lines 40i is a wiring line that transmits an initialization signal. The plurality of second initialization lines 40i are provided at intervals between each other in the second direction Y in the display region DA, and extend in parallel to each other in the first direction X. The second initialization line 40i is provided for each row of the subpixels SP. Each of the second initialization lines 40i is connected to the drive circuit DC.

Each of the plurality of power source lines 40p applies a predetermined high-level power supply voltage (ELVDD). The plurality of power source lines 40p are disposed at intervals between each other in the first direction X in the display region DA, and extend in parallel to each other in the second direction Y. The power source line 40p is provided for each row of the subpixels SP. Each power source line 40p is connected to the first frame line 40fa.

Each of the plurality of source lines 40s is a wiring line that transmits a source signal. The plurality of source lines 40s are disposed at intervals between each other in the first direction X in the display region DA, and extend in parallel to each other in the second direction Y. The source line 40s is provided for each row of the subpixels SP. Each source line 40s is extended to the terminal portion TP and connected to the display control circuit via the wiring line substrate CB.

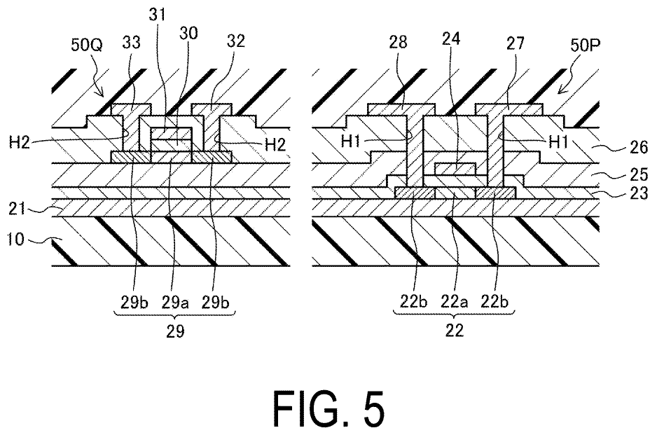

The plurality of TFTs 50 are provided for each subpixel SP. The plurality of TFTs 50 provided for each subpixel SP include a polysilicon TFT 50P illustrated in FIG. 5 (right drawing) and an oxide semiconductor TFT 50Q illustrated in FIG. 5 (left drawing). The polysilicon TFT 50P is an example of a second thin film transistor. The oxide semiconductor TFT 50Q is an example of a first thin film transistor. The polysilicon TFT 50P and the oxide semiconductor TFT 50Q constitute a pixel circuit PC.

The polysilicon TFT 50P is configured to be a top gate type. The polysilicon TFT 50P includes a first semiconductor layer 22, a first gate insulating film 23, a first gate electrode 24, a first interlayer insulating film 25, a second interlayer insulating film 26, a first terminal electrode 27, and a second terminal electrode 28.

The first semiconductor layer 22 is provided in an island shape on the base coat film 21. The first semiconductor layer 22 is individually separated for each polysilicon TFT 50P. The first semiconductor layer 22 may be continuously provided through a plurality of the polysilicon TFTs 50P. The first semiconductor layer 22 includes a channel region 22a and a pair of conductive regions 22b. The channel region 22a is provided between the pair of conductive regions 22b. The pair of conductive regions 22b is provided separate from each other with the channel region 22a interposed therebetween.

The first gate insulating film 23 is continuously provided through the plurality of polysilicon TFTs 50P so as to cover a plurality of the first semiconductor layers 22. The first gate insulating film 23 may be provided in an island shape on each of the first semiconductor layers 22, and may be individually separated for each polysilicon TFT 50P. The first gate electrode 24 is provided on the first gate insulating film 23. The first gate electrode 24 overlaps the first semiconductor layer 22 (channel region 22a) via the first gate insulating film 23.

The first interlayer insulating film 25 and the second interlayer insulating film 26 are layered in this order on the first gate insulating film 23, and are provided to cover a plurality of the first gate electrodes 24. A pair of first contact holes H1 is formed for each polysilicon TFT 50P in a layered film formed of the first gate insulating film 23, the first interlayer insulating film 25, and the second interlayer insulating film 26. The pair of first contact holes H1 passes through mutually different conductive regions 22b of the first semiconductor layer 22.

The first terminal electrode 27 and the second terminal electrode 28 are provided on the second interlayer insulating film 26. The first terminal electrode 27 and the second terminal electrode 28 are separated from each other. The first and second terminal electrodes 27 and 28 are connected to the first semiconductor layer 22 through different first contact holes H1. In the first semiconductor layer 22, the first terminal electrode 27 is connected to one conductive region 22b, while the second terminal electrode 28 is connected to the other conductive region 22b.

The oxide semiconductor TFT 50Q is configured to be a top gate type. The oxide semiconductor TFT 50Q includes a second semiconductor layer 29, a second gate insulating film 30, a second gate electrode 31, the second interlayer insulating film 26, a third terminal electrode 32, and a fourth terminal electrode 33.

The second semiconductor layer 29 is provided in an island shape on the first interlayer insulating film 25. The second semiconductor layer 29 is individually separated for each oxide semiconductor TFT 50Q. The second semiconductor layer 29 may be continuously provided through a plurality of the oxide semiconductor TFTs 50Q. The second semiconductor layer 29 includes a channel region 29a and a pair of conductive regions 29b. The channel region 29a is provided between the pair of conductive regions 29b. The pair of conductive regions 29b is provided separate from each other with the channel region 29b interposed therebetween.

The second gate insulating film 30 is provided in an island shape on each of the second semiconductor layers 29, and is individually separated for each oxide semiconductor TFT 50Q. The second gate insulating film 30 may be continuously provided through the plurality of oxide semiconductor TFTs 50Q so as to cover a plurality of the second semiconductor layers 29. The second gate electrode 31 is provided on the second gate insulating film 30. The second gate electrode 31 overlaps the second semiconductor layer 29 (channel region 29a) via the second gate insulating film 30.

The second interlayer insulating film 26 is provided to cover a plurality of the second gate electrodes 31. The second interlayer insulating film 26 of the present example covers the plurality of second semiconductor layers 29 and the second gate insulating film 30 together with each second gate electrode 31. A pair of second contact holes H2 is formed in the second interlayer insulating film 26 for each of the oxide semiconductor TFTs 50Q. The pair of second contact holes H2 passes through mutually different conductive regions 29b of the second semiconductor layer 29.

The third terminal electrode 32 and the fourth terminal electrode 33 are provided on the second interlayer insulating film 26. The third terminal electrode 32 and the fourth terminal electrode 33 are separated from each other. The third and fourth terminal electrodes 32 and 33 are connected to the second semiconductor layer 29 through different second contact holes H2. In the second semiconductor layer 29, the third terminal electrode 32 is connected to one conductive region 29b, while the fourth terminal electrode 33 is connected to the other conductive region 29b.

At least one capacitor 55 is provided for each subpixel PS. As illustrated in FIG. 4, the capacitor 55 includes a first capacitance electrode 34 and a second capacitance electrode 35. The first capacitance electrode 34 is provided on the first gate insulating film 23. The second capacitance electrode 35 is provided on the first interlayer insulating film 25. The first capacitance electrode 34 and the second capacitance electrode 35 overlap each other via the first interlayer insulating film 25.

The base coat film 21, the first gate insulating film 23, the first interlayer insulating film 25, the second interlayer insulating film 26, and the second gate insulating film 30 include an inorganic insulating material such as silicon oxide, silicon nitride, or silicon oxynitride. These various insulating films are constituted by a single-layer film or a layered film formed of an inorganic insulating material.

The first interlayer insulating film 25 of the present example is constituted of a layered film in which a silicon nitride film and a silicon oxide film are layered in this order. The second interlayer insulating film 26 of the present example is constituted of a layered film in which a silicon oxide film and a silicon nitride film are layered in this order. The second gate insulating film 30 of the present example is constituted of a single-layer film of a silicon oxide film.

The first semiconductor layer 22 is formed of polysilicon. The polysilicon forming the first semiconductor layer 22 is, for example, low temperature polycrystalline silicon (LTPS). The second semiconductor layer 29 is formed of a transparent oxide semiconductor. The oxide semiconductor forming the second semiconductor layer 29 is, for example, an In—Ga—Zn—O based semiconductor.

The In—Ga—Zn—O based semiconductor is a ternary oxide of indium (In), gallium (Ga), and zinc (Zn). The ratio of In, Ga, and Zn (composition ratio) of the In—Ga—Zn—O based semiconductor is not restricted. The In—Ga—Zn—O based semiconductor may be amorphous or may be noncrystalline. The second semiconductor layer 29 may include one or more types of other oxide semiconductors in addition to or in place of the In—Ga—Zn—O based semiconductor.

Examples of the other oxide semiconductors may include an In—Sn—Zn—O based semiconductor. Examples of the In—Sn—Zn—O based semiconductor include In₂O₃—SnO₂—ZnO (InSnZnO). Here, the In—Sn—Zn—O based semiconductor is a ternary oxide of indium (In), tin (Sn), and zinc (Zn).

Alternatively, examples of the other oxide semiconductors may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), an Mg—Zn—O based semiconductor, and an In—Ga—Sn—O based semiconductor.

Alternatively, examples of the other oxide semiconductors may include an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃ (ZnO)₅, magnesium zinc oxide (MgₓZn₁₋ₓO), and cadmium zinc oxide (CdₓZn₁₋ₓO).

The first gate electrodes 24, the first capacitance electrodes 34, the gate lines 40g, and the light emission control lines 40e are formed of the same material and in the same layer. The second capacitance electrodes 35 and the second initialization lines 40i are formed of the same material and in the same layer. The first, second, third and fourth terminal electrodes 27, 28, 32 and 33, the power source lines 40p, and the source lines 40s are formed of the same material and in the same layer.

The above-mentioned various wiring lines and electrodes are each made of a metal material such as aluminum (Al), tungsten (W), molybdenum (Mo), tantalum (Ta), chromium (Cr), titanium (Ti), or copper (Cu). These various wiring lines and electrodes are each constituted by a single-layer film or a layered film including a metal material.

As illustrated in FIG. 4, the TFT layer 20 further includes a first flattening film 37 and a second flattening film 38. The first flattening film 37 and the second flattening film 38 are layered in this order on the second interlayer insulating film 26 and cover the plurality of TFTs 50 and the plurality of capacitors 55. The first flattening film 37 and the second flattening film 38 are provided over the entire display region DA and also extend to the frame region FA.

The surface of the TFT layer 20 is flattened by the first flattening film 37 and the second flattening film 38. The first flattening film 37 and the second flattening film 38 are each made of, for example, an organic resin material such as a polyimide resin or an acrylic resin, or a polysiloxane-based spin on glass (SOG) material. A plurality of relay lines 40r are provided in an island shape on the first flattening film 37.

Each of the plurality of relay lines 40r relays connection between an organic EL element 70 and a predetermined TFT 50 (a light emission control TFT 50f, an anode electrode discharge TFT 50g). The relay line 40r is provided for each of the subpixels SP. The relay line 40r is connected to the predetermined TFT 50 (the second terminal electrode 28 of the light emission control TFT 50f, the third terminal electrode 32 of the anode electrode discharge TFT 50g) via a third contact hole H3 formed in the first flattening film 37.

### Light-Emitting Element Layer

The light-emitting element layer 60 is provided on the TFT layer 20. The light-emitting element layer 60 includes a plurality of the organic electroluminescence elements (organic EL elements) 70 and an edge cover 75, as illustrated in FIG. 4. The organic EL element 70 is an example of a light-emitting element. The plurality of organic EL elements 70 are each configured as a top-emitting type. In the organic EL element 70, light emitted in an organic EL layer 62 is extracted from a sealing film 80 side.

Each of the plurality of organic EL elements 70 constitutes the subpixel SP. The plurality of organic EL elements 70 constitute the display region DA as a whole. Light emission of each of the organic EL elements 70 is controlled by operations of the plurality of TFTs 50 and the capacitor 55. Each of the organic EL elements 70 includes a pixel electrode 61, the organic EL layer 62, and a common electrode 63.

The pixel electrode 61 is provided on the second flattening film 38 in each subpixel SP. The pixel electrodes 61 are arrayed in a matrix shape corresponding to the subpixels SP. The pixel electrode 61 is connected to the relay line 40r through a fourth contact hole H4 formed in the second flattening film 38. The pixel electrode 61 functions as an anode electrode, and injects holes into the organic EL layer 62. A conductive material having a large work function is preferably used for the pixel electrode 61.

Examples of the material of the pixel electrode 61 include metals such as silver (Ag), aluminum (Al), nickel (Ni), titanium (Ti), indium (In), and tin (Sn). The material of the pixel electrode 61 may be a metal compound or an alloy. The material of the pixel electrode 61 may be, for example, a conductive oxide such as indium tin oxide (ITO) or indium zinc oxide (IZO). The pixel electrode 61 may be formed by layering a plurality of layers including a conductive material.

The edge cover 75 is provided on the second flattening film 38 so as to define a plurality of the pixel electrodes 61. The edge cover 75 is formed in a lattice pattern common to all the subpixels SP and covers a circumferential end portion of each pixel electrode 61. The edge cover 75 is made of, for example, an organic resin material such as a polyimide resin or an acrylic resin, or a polysiloxane-based SOG material.

The organic EL layer 62 is provided on the individual pixel electrode 61 in an opening 76 of the edge cover 75. The organic EL layer 62 includes a hole injection layer, a hole transport layer, a light-emitting layer, an electron transport layer, and an electron injection layer. The hole injection layer, the hole transport layer, the light-emitting layer, the electron transport layer, and the electron injection layer are layered in this order on the pixel electrode 61, and are made of known compounds suitable for the respective functions. The organic EL layer 62 emits light when a current flows between the pixel electrode 61 and the common electrode 63.

The common electrode 63 is continuously provided to be common to the plurality of subpixels SP over the entire display region DA. The common electrode 63 covers the edge cover 75 and each organic EL layer 62, and overlaps each pixel electrode 61 via the organic EL layer 62. The common electrode 63 extends to the frame region FA and is connected to the second frame line 40fb. The common electrode 63 functions as a cathode electrode, and injects electrons into the organic EL layer 62. A conductive material having a small work function is preferably used for the common electrode 63.

Examples of the material of the common electrode 63 include an electrically conductive oxide such as indium tin oxide (ITO) or indium zinc oxide (IZO). The material of the common electrode 63 may be a metal such as silver (Ag), aluminum (Al), lithium (Li), magnesium (Mg), calcium (Ca), or ytterbium (Yb). The material of the common electrode 63 may be a metal compound or an alloy. The common electrode 63 may be formed by layering a plurality of layers including a conductive material.

### Sealing Film

The sealing film 80 is provided on the light-emitting element layer 60. As illustrated in FIG. 4, the sealing film 80 covers the plurality of organic EL elements 70 and protects each of the organic EL elements 70 (particularly, the organic EL layer 62) from moisture, oxygen, and the like. The sealing film 80 is provided over the entire display region DA and extends to the frame region FA. The sealing film 80 has, for example, a thin film encapsulation (TFE) structure. The sealing film 80 includes a first inorganic film 81, an organic film 82, and a second inorganic film 83. The first inorganic film 81, the organic film 82, and the second inorganic film 83 are provided in this order on the light-emitting element layer 60.

The first inorganic film 81 and the second inorganic film 83 extend closer to the outer peripheral side of the frame region FA than the organic film 82, and overlap each other in the peripheral edge portion of the frame region FA. The organic film 82 is enclosed by the first inorganic film 81 and the second inorganic film 83. The first inorganic film 81 and the second inorganic film 83 each include, for example, an inorganic insulating material such as silicon oxide, silicon nitride, or silicon oxynitride. The organic film 82 includes, for example, an organic resin material such as an acrylic resin, an epoxy resin, a silicone resin, a polyurea resin, a parylene resin, a polyimide resin, or a polyamide resin.

### Pixel Circuit

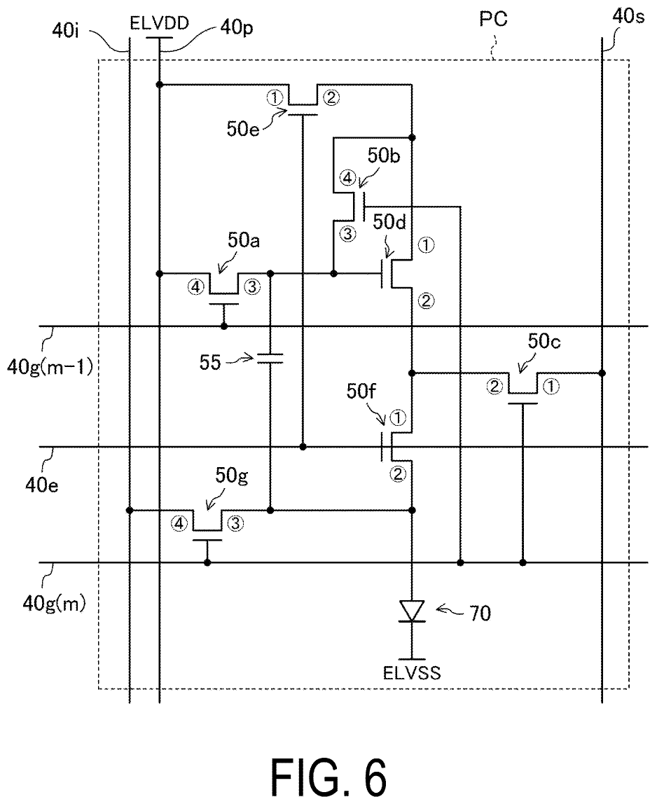

The plurality of TFTs 50 and the capacitors 55, provided for each subpixel SP, constitute the pixel circuit PC as illustrated in FIG. 6. The pixel circuit PC controls light emission of the organic EL element 70 based on a gate signal, an emission signal, a source signal, an initialization signal, a high-level power supply voltage, and a low-level power supply voltage that are supplied through various wiring lines.

The plurality of TFTs 50 constituting the pixel circuit PC are an initialization TFT 50a, a compensation TFT 50b, a writing TFT 50c, a drive TFT 50d, a power supply TFT 50e, the light emission control TFT 50f, and the anode electrode discharge TFT 50g. Each of the writing TFT 50c, the drive TFT 50d, the power supply TFT 50e, and the light emission control TFT 50f is formed of the polysilicon TFT 50P. Each of the initialization TFT 50a, the compensation TFT 50b, and the anode electrode discharge TFT 50g is formed of the oxide semiconductor TFT 50Q.

The pixel circuit PC illustrated in FIG. 6 is the pixel circuit PC of the subpixel SP at the m-th row and n-th column (m and n are positive integers). In the equivalent circuit diagram of FIG. 6, the first terminal electrode 27 of the polysilicon TFT 50P is indicated by the encircled number 1, and the second terminal electrode 28 is indicated by the encircled number 2. In the equivalent circuit diagram of FIG. 6, the third and fourth terminal electrodes 32 and 33 of the oxide semiconductor TFT 50Q are indicated by the encircled numbers 3 and 4, respectively.

In the equivalent circuit diagram of FIG. 6, the gate line 40g with “(m)” added to the reference sign is the gate line 40g at the stage of the gate line 40g itself (m-th stage) corresponding to the subpixels in the m-th row. Furthermore, in the equivalent circuit diagram of FIG. 6, the gate line 40g with “(m−1)” added to the reference sign is the gate line 40g at the (m−1)-th stage that is scanned preceding the gate line 40g at the m-th stage.

In the equivalent circuit diagram of FIG. 6, the power source line 40p also serves as a first initialization line. The first initialization line may be provided separately from the power source line 40p. The same voltage as the low-level power supply voltage (ELVSS) is input to the second initialization line 40i as an initialization signal. A voltage that is different from the low-level power supply voltage (ELVSS) and turns off the organic EL element 70 may be input to the second initialization line 40i.

The gate electrode (second gate electrodes 31) of the initialization TFT 50a is connected to the gate line (m−1) of the preceding stage ((m−1)-th stage). The third terminal electrode 32 of the initialization TFT 50a is connected to the first capacitance electrode 34 of the capacitor 55 and to the gate electrode (first gate electrode 24) of the drive TFT 50d. The fourth terminal electrode 33 of the initialization TFT 50a is connected to the power source line 40p.

The gate electrode (second gate electrodes 31) of the compensation TFT 50b is connected to the gate line 40g at the stage of the compensation TFT 50b itself (m-th stage). The third terminal electrode 32 of the compensation TFT 50b is connected to the gate electrode (first gate electrode 24) of the drive TFT 50d. The fourth terminal electrode 33 of the compensation TFT 50b is connected to the first terminal electrode 27 of the drive TFT 50d.

The gate electrode (first gate electrode 24) of the writing TFT 50c is connected to the gate line 40g at the stage of the writing TFT 50c itself (m-th stage). The first terminal electrode 27 of the writing TFT 50c is electrically connected to the corresponding source line 40s. The second terminal electrode 28 of the writing TFT 50c is connected to the second terminal electrode 28 of the drive TFT 50d.

The gate electrode (first gate electrode 24) of the drive TFT 50d is connected to the third terminal electrodes 32 of the initialization TFT 50a and the compensation TFT 50b. The first terminal electrode 27 of the drive TFT 50d is connected to the fourth terminal electrode 33 of the compensation TFT 50b and the second terminal electrode 28 of the power supply TFT 50e. The second terminal electrode 28 of the drive TFT 50d is connected to the second terminal electrode 28 of the writing TFT 50c and the first terminal electrode 27 of the light emission control TFT 50f.

The gate electrode (first gate electrode 24) of the power supply TFT 50e is connected to the light emission control line 40e at the stage of the power supply TFT 50e itself (m-th stage). The first terminal electrode 27 of the power supply TFT 50e is connected to the power source line 40p. The second terminal electrode 28 of the power supply TFT 50e is connected to the first terminal electrode 27 of the drive TFT 50d.

The gate electrode (first gate electrode 24) of the light emission control TFT 50f is connected to the light emission control line 40e at the stage of the light emission control TFT 50f itself (m-th stage). The first terminal electrode 27 of the light emission control TFT 50f is connected to the second terminal electrode 28 of the drive TFT 50d. The second terminal electrode 28 of the light emission control TFT 50f is connected to the pixel electrode 61 of the organic EL element 70.

The gate electrode (second gate electrodes 31) of the anode electrode discharge TFT 50g is connected to the gate line 40g at the stage of the anode electrode discharge TFT 50g itself (n). The third terminal electrode 32 of the anode electrode discharge TFT 50g is connected to the pixel electrode 61 of the organic EL element 70. The fourth terminal electrode 33 of the anode electrode discharge TFT 50g is connected to the second initialization line 40i.

The first capacitance electrode 34 of the capacitor 55 is connected to the gate electrode (first gate electrode 24) of the drive TFT 50d and to the third terminal electrodes 32 of the initialization TFT 50a and the compensation TFT 50b. The second capacitance electrode 35 of the capacitor 55 is connected to the second terminal electrode 28 of the light emission control TFT 50f and the pixel electrode 61 of the organic EL element 70.

### Disposition Configuration of Organic EL Elements and Pixel Circuits

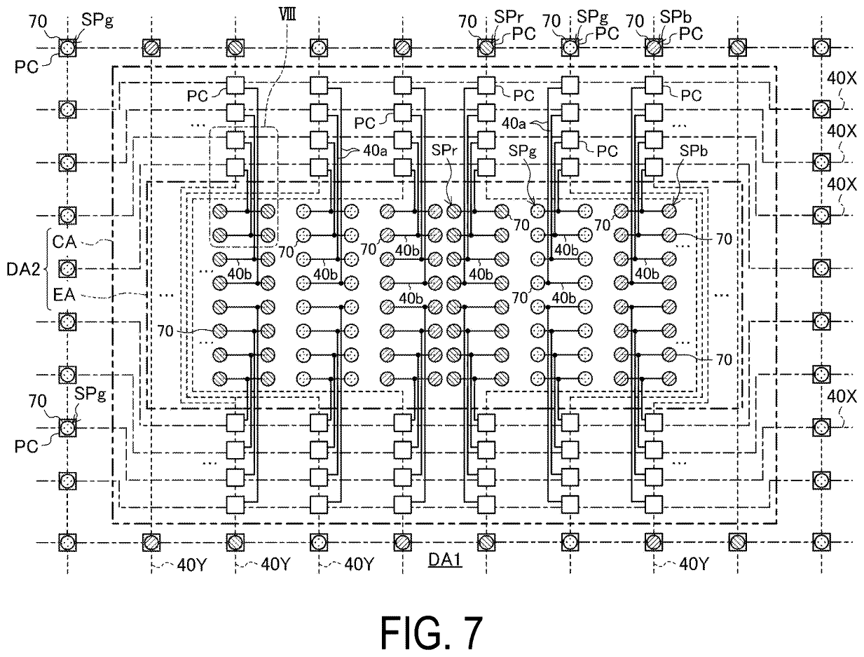

As illustrated in FIG. 7, in the second display region DA2, a disposition relationship between the organic EL elements 70 and the pixel circuits PC is different from that in the first display region DA1, and various wiring lines extend irregularly. FIG. 7 schematically exemplifies the disposition relationship between the organic EL elements 70 and the pixel circuits PC in the second display region DA2 and in the first display region DA1 around the second display region DA2.

In the schematic view illustrated in FIG. 7, for convenience, the organic EL element 70 is depicted by a circular symbol figure, and the pixel circuit PC is depicted by a rectangular symbol figure. In the schematic view of FIG. 7, the organic EL element 70 configured to emit red light is hatched with leftward inclined lines, the organic EL element 70 configured to emit green light is hatched with dots, and the organic EL element 70 configured to emit blue light is hatched with rightward inclined lines.

In the schematic view of FIG. 7, for convenience, the gate line 40g, the light emission control line 40e, and the second initialization line 40i are indicated by a chain line as one representative wiring line (first metal line 40X). Each of the gate line 40g, the light emission control line 40e, and the second initialization line 40i extends in the same shape as the first metal line 40X. In the schematic view of FIG. 7, for convenience, the source line 40s and the power source line 40p are indicated by a broken line as one representative wiring line (second metal line 40Y). Each of the source line 40s and the power source line 40p extends in the same shape as the second metal line 40Y.

In the first display region DA1, the pixel circuits PC are disposed at the positions overlapping the corresponding organic EL elements 70 in a plan view and near the periphery thereof. This is indicated by overlapping and depicting the organic EL elements 70 and the pixel circuits PC in FIG. 7. In other words, in the first display region DA1, each of the pixel circuits PC is provided at a position overlapping the subpixel SP formed by the organic EL element 70 corresponding to each of the pixel circuits PC.

In contrast, in the second display region DA2, the pixel circuits PC are disposed at separate positions where the pixel circuits PC do not overlap the corresponding organic EL elements 70 in a plan view. That is, in the second display region DA2, a region in which the organic EL elements 70 forming the subpixels SP are disposed and a region in which a plurality of the pixel circuits PC corresponding to the organic EL elements 70 are disposed are provided separately from each other.

Specifically, the second display region DA2 includes a light-emitting element region EA and a circuit disposition region CA. The light-emitting element region EA is provided in a central portion of the second display region DA2. The plurality of organic EL elements 70 are disposed in the light-emitting element region EA. The circuit disposition region CA is provided around the light-emitting element region EA. The plurality of pixel circuits PC are provided in the circuit disposition region CA. The pixel circuits PC control light emission of the organic EL elements 70 disposed in the light-emitting element region EA.

In the light-emitting element region EA, a plurality of sets of the organic EL elements 70 are disposed, where each set includes two organic EL elements 70 adjacent to each other. The two organic EL elements 70 forming each set are disposed side by side in the first direction X. These two organic EL elements 70 emit light of the same color. The pixel circuit PC is provided for each set of the organic EL elements 70, and commonly controls light emission of the two organic EL elements 70 of the set.

In the second display region DA2, a plurality of first connection lines 40a and a plurality of second connection lines 40b are provided. The first connection lines 40a and the second connection lines 40b are wiring lines for connecting each set of the organic EL elements 70 and the pixel circuit PC, and are provided for each combination of a set of the organic EL elements 70 and the pixel circuit PC.

The first connection line 40a is connected to each of the two organic EL elements 70 forming the corresponding set, and connects the two organic EL elements 70 to each other. The second connection line 40b is connected to the first connection line 40a and the pixel circuit PC, strictly speaking, to predetermined TFTs 50 (light emission control TFT 50f, anode electrode discharge TFT 50g) included in the pixel circuit PC, and connects the first connection line 40a and the predetermined TFTs 50.

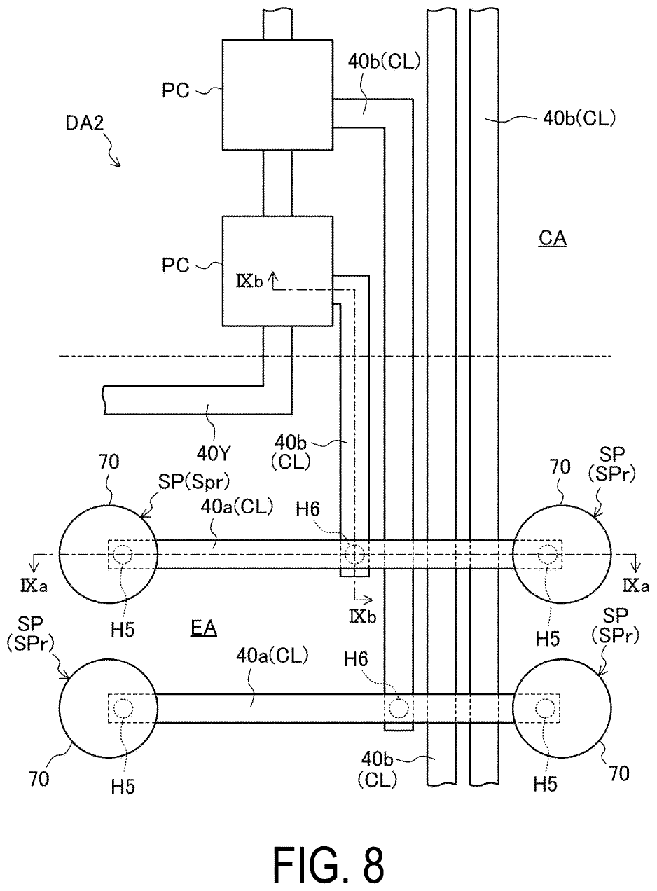

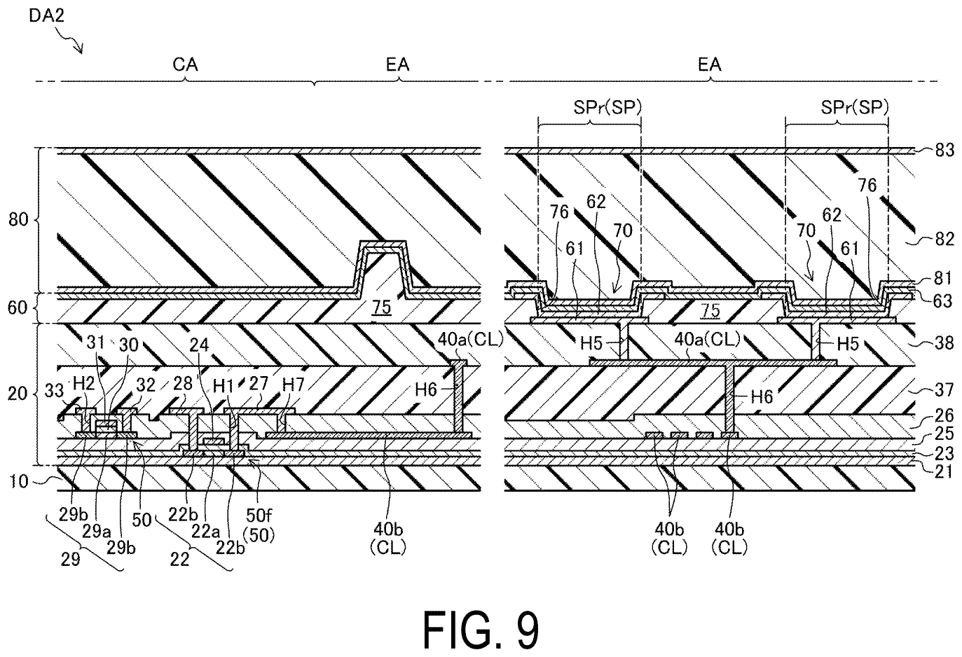

The first connection line 40a and the second connection line 40b are formed in layers different from each other. As illustrated in FIG. 8, some of the first connection lines 40a and second connection lines 40b not connected to each other are disposed to extend while intersecting each other in a plan view. As illustrated in FIG. 9, the second interlayer insulating film 26 and the first flattening film 38 are interposed between the first connection line 40a and the second connection line 40b.

The first connection line 40a is provided on the first flattening film 37 and is covered with the second flattening film 38. The pixel electrodes 61 of the two organic EL elements 70 forming each set are connected to the common first connection line 40a through fifth contact holes H5 formed in the second flattening film 38. The second connection line 40b is provided on the first interlayer insulating film 25 and is covered with the second interlayer insulating film 26.

To the second connection line 40b, the corresponding first connection line 40a is connected through a sixth contact hole H6 formed in the second interlayer insulating film 26 and the first flattening film 37. Further, to the second connection line 40b, the electrode of the predetermined TFT 50 (the second terminal electrode 28 of the light emission control TFT 50f, the third terminal electrode 32 of the anode electrode discharge TFT 50g) included in the corresponding pixel circuit PC is connected through a seventh contact hole H7 formed in the second interlayer insulating film 26.

Each of the first connection line 40a and the second connection line 40b has optical transparency. The second connection line 40b is formed in the same layer as the layer of the first semiconductor layer 22, and is constituted of a conductor layer CL obtained by converting an oxide semiconductor into a conductor. The first connection line 40a is constituted of the conductor layer CL obtained by converting the same type of oxide semiconductor as the second connection line 40b into a conductor. The conductor layer CL is formed by reducing an oxide semiconductor. The conductor layer CL discussed above is transparent and has a low degree of absorption of wavelengths in the visible light region.

The first connection lines 40a are each formed of the same material and in the same layer as each relay line 40r. That is, each of the relay lines 40r is formed of the conductor layer CL obtained by converting an oxide semiconductor into a conductor. The first connection lines 40a and the relay lines 40r are each constituted by a single-layer film or a layered film made of an oxide semiconductor having been converted into a conductor.

As illustrated in FIG. 7, the first metal lines 40X corresponding to the plurality of subpixels SP in the second display region DA2 extend via the outer side of a group of the organic EL elements 70 disposed in the light-emitting element region EA. Each of the first metal lines 40X extends in the circuit disposition region CA while being away from the light-emitting element region EA, and is connected to the pixel circuit PC (the first terminal electrode 27 of the writing TFT 50c) in the circuit disposition region CA. The second metal lines 40Y corresponding to the plurality of subpixels SP in the second display region DA2 extend via the outer side of the group of the organic EL elements 70 disposed in the light-emitting element region EA.

As described above, in the second display region DA2, the first connection lines 40a, the second connection lines 40b, the first metal lines 40X, and the second metal lines 40Y are designed so as not to lower the transmittance of light from the front face side to the back face side in the light-emitting element region EA.

### Operation of Organic EL Display Device

In the organic EL display device 1, in each subpixel SP, first, the corresponding light emission control line 40e is selected, and an emission signal indicating an inactive state is input to the power supply TFT 50e and the light emission control TFT 50f via the selected light emission control line 40e. As a result, the power supply TFT 50e and the light emission control TFT 50f are turned off, and the organic EL element 70 is set to be in a non-light emission state.

Then, the gate line 40g(m−1) to be scanned preceding the corresponding gate line 40g is selected, and a gate signal indicating an active state is input to the initialization TFT 50a via the selected gate line 40g(m−1). As a result, the initialization TFT 50a is turned on. Due to this, the charge of the capacitor 55 is discharged to initialize the voltage applied to the gate electrode of the drive TFT 50d.

Subsequently, the corresponding gate line 40g is selected, and a gate signal indicating an active state is input to the compensation TFT 50b and the writing TFT 50c via the selected gate line 40g. As a result, the compensation TFT 50b and the writing TFT 50c are turned on. Due to this, the drive TFT 50d is brought into a diode connection state, and a predetermined voltage corresponding to a source signal transmitted via the source line 40s is written to the capacitor 55.

When the corresponding gate line 40g is selected, a gate signal indicating an active state is also input to the anode electrode discharge TFT 50g via the selected gate line 40g. As a result, the anode electrode discharge TFT 50g is turned on. Due to this, an initialization signal is applied to the pixel electrode 61 of the organic EL element 70 via the second initialization line 40i, and the charge accumulated in the pixel electrode 61 is reset.

Thereafter, the corresponding light emission control line 40e is selected, and an emission signal indicating an active state is input to the power supply TFT 50e and the light emission control TFT 50f. Due to this, the power supply TFT 50e and the light emission control TFT 50f are turned on, and a drive current corresponding to the voltage applied to the gate electrode (first gate electrode 24) of the drive TFT 50d is supplied from the power source line 40p to the organic EL element 70.

In this way, in the organic EL display device 1, in each subpixel SP, the organic EL element 70 emits light at luminance corresponding to the drive current, whereby image display is performed.

### Manufacturing Method of Organic EL Display Device

To manufacture the organic EL display device 1, first, the substrate layer 10 is formed by applying an organic resin material onto the surface of a glass substrate and performing baking treatment. Subsequently, the TFT layer 20, the light-emitting element layer 60, and the sealing film 80 are sequentially formed on the substrate layer 10 using a known film forming method such as a chemical vapor deposition (CVD) technique, sputtering, or a vacuum vapor deposition technique, a known coating method such as a spin coating method or an ink-jet method, and a known patterning technique such as photolithography.

Then, the glass substrate is peeled off from the substrate layer 10 by, for example, irradiating the rear surface of the substrate layer 10 with a laser beam from the glass substrate side. Subsequently, a polarizer, a cover panel, or the like is bonded to the surface of the sealing film 80. Further, a protection film is bonded to the back face of the substrate layer 10. Furthermore, the display control circuit is mounted by connecting the wiring line substrate CB to the terminal portion TP. Thereafter, the organic EL display device 1 is accommodated in the housing together with the camera 3, and the camera 3 is installed at a position overlapping the second display region DA2 in a plan view on the back face side of the organic EL display device 1.

The organic EL display device 1 can be manufactured in the manner described above.

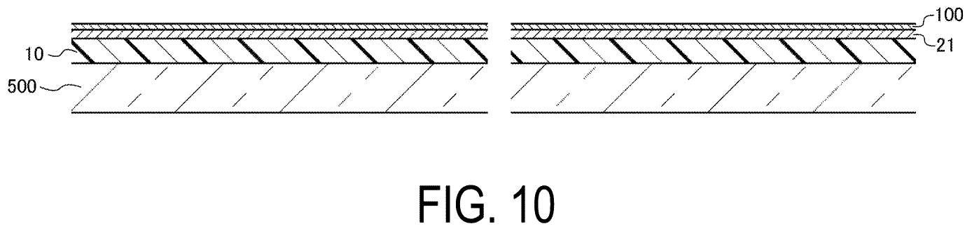

In the process of forming the TFT layer 20, first, a silicon nitride film and a silicon oxide film are sequentially formed on the substrate layer 10 formed on a glass substrate 500 by, for example, a plasma CVD technique. Thus, the base coat film 21 is formed (see FIG. 10).

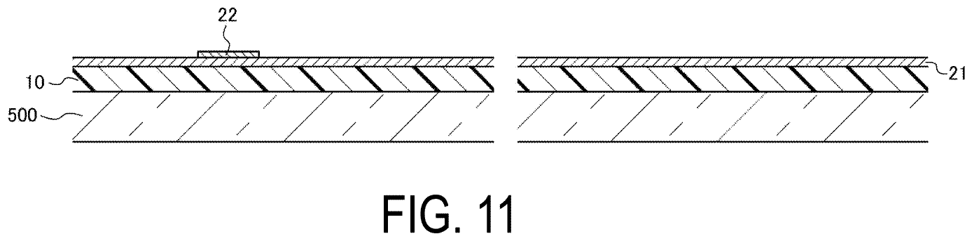

Subsequently, an amorphous silicon film is formed on the substrate on which the base coat film 21 is formed by, for example, a plasma CVD technique, and the amorphous silicon film is crystallized by laser annealing or the like to form a first semiconductor film 100 made of polysilicon as illustrated in FIG. 10. Thereafter, the first semiconductor film 100 is patterned to form the first semiconductor layer 22 as illustrated in FIG. 11.

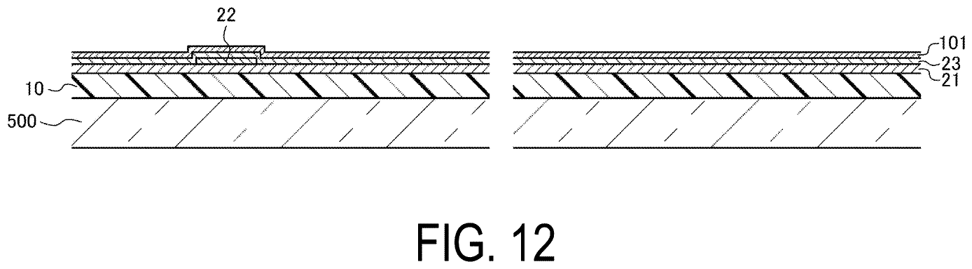

Further, a silicon oxide film is formed by, for example, a plasma CVD technique on the substrate on which the first semiconductor layer 22 is formed. By doing so, the first gate insulating film 23 is formed. Subsequently, on the substrate on which the first gate insulating film 23 is formed, a molybdenum film or the like is formed by, for example, a sputtering technique. By doing so, as illustrated in FIG. 12, a first metal film 101 is formed. Subsequently, the first metal film 101 is patterned to form the first gate electrode 24. At this time, the first capacitance electrodes 34, the gate lines 40g, and the light emission control lines 40e are formed at the same time.

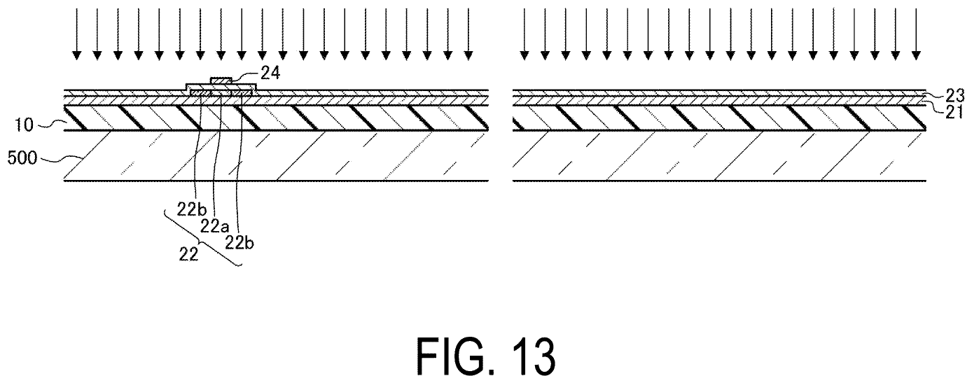

Subsequently, as illustrated in FIG. 13, the surface of the substrate on which the first gate electrode 24 is formed is doped with impurity ions such as phosphorus by using the first gate electrode 24 as a mask. With this, the channel region 22a and the pair of conductive regions 22b are formed in the first semiconductor layer 22. Further, a silicon nitride film and a silicon oxide film are sequentially formed on the substrate doped with the impurity ions, by a plasma CVD technique. As a result, the first interlayer insulating film 25 is formed.

Next, on the substrate on which the first interlayer insulating film 25 is formed, a titanium film, an aluminum film, or the like is formed by, for example, a sputtering technique. By doing so, the second metal film is formed. Subsequently, the second metal film is patterned to form the second capacitance electrodes 35 and the second initialization lines 40i.

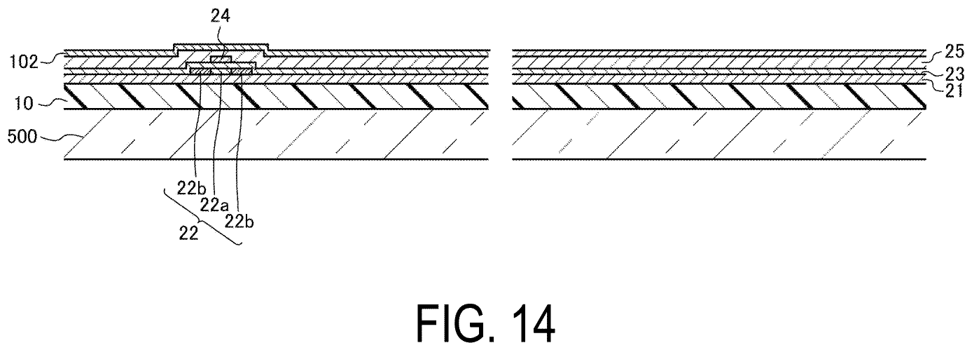

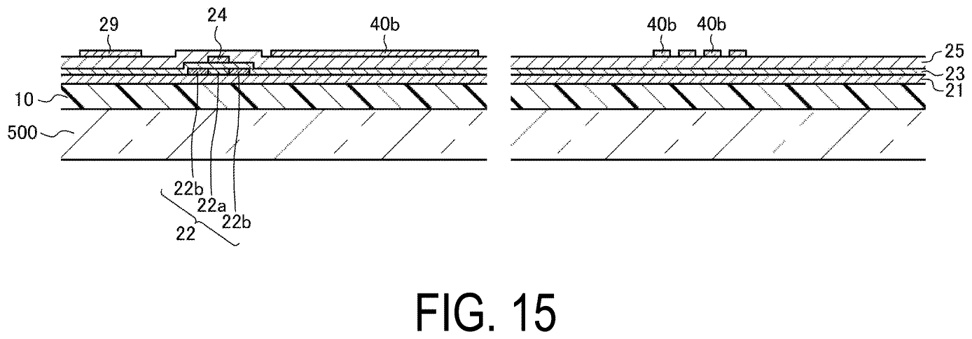

Next, as illustrated in FIG. 14, on the substrate on which the second capacitance electrodes 35 and the like are formed, a second semiconductor film 102 made of an oxide semiconductor such as InGaZnO₄ is formed by, for example, a plasma CVD technique. Then, the second semiconductor film 102 is patterned to form the second semiconductor layer 29 and the second connection lines 40b are formed as illustrated in FIG. 15.

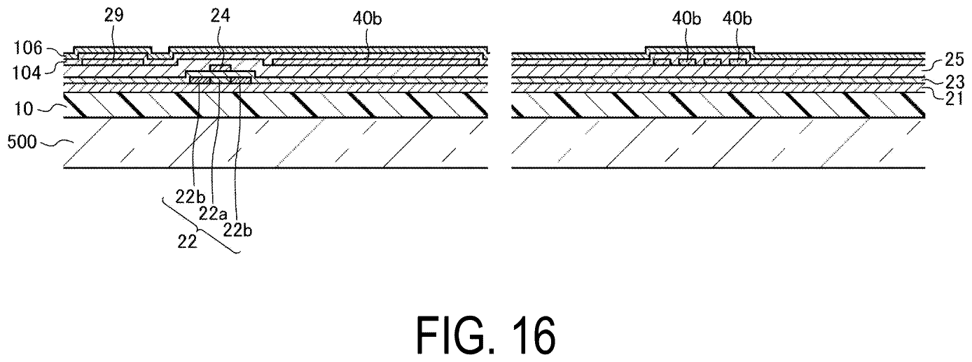

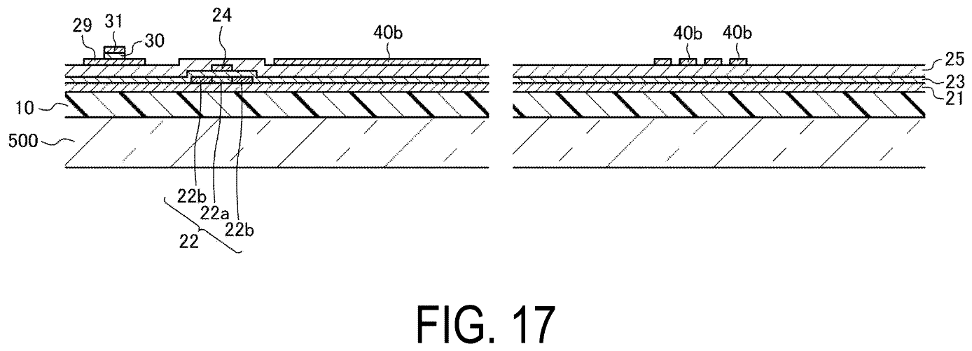

Subsequently, a silicon oxide film is formed by, for example, a plasma CVD technique on the substrate on which the second semiconductor layer 29 and the like are formed. With this, a first insulating film 104 is formed. Further, on the substrate on which the first insulating film 104 is formed, a molybdenum film or the like is formed by, for example, a sputtering technique. Thus, as illustrated in FIG. 16, a third metal film 106 is formed. Subsequently, the first insulating film 104 and the third metal film 106 are patterned to form the second gate insulating film 30 and the second gate electrode 31 as illustrated in FIG. 17.

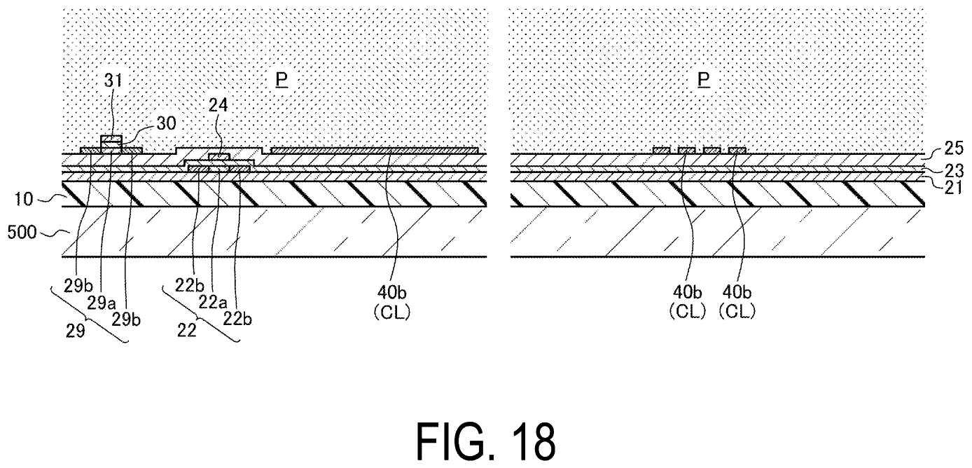

Then, as illustrated in FIG. 18, the surface of the substrate on which the second gate electrode 31 and the like are formed is subjected to hydrogen plasma treatment using the second gate electrode 31 as a mask. The exposed portion of the second semiconductor layer 29 and the entire second connection lines 40b are exposed to plasma P by the hydrogen plasma treatment. When the oxide semiconductor forming the second semiconductor layer 29 and the second connection line 40b is exposed to the plasma P, the resistance thereof is lowered due to the occurrence of oxygen deficiency. With this, the channel region 29a and the pair of conductive regions 29b are formed in the second semiconductor layer 29. Further, the entire second connection line 40b is made to be a conductor.

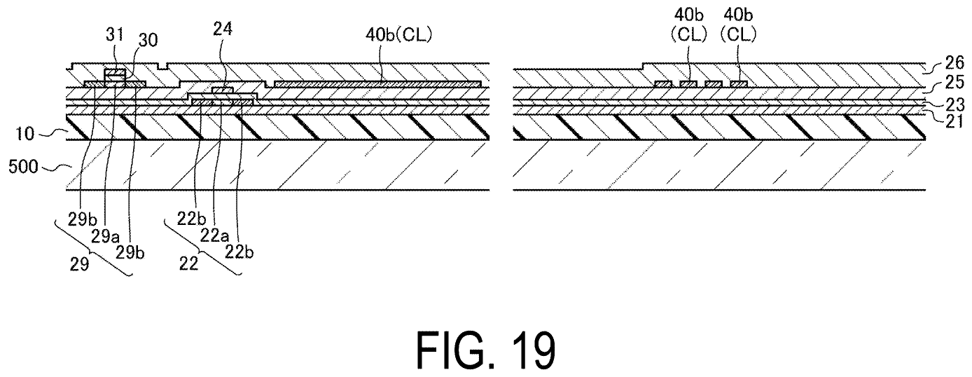

Further, a silicon oxide film and a silicon nitride film are sequentially formed by, for example, a plasma CVD technique on the substrate on which the second gate electrode 31 and the like are formed. Thus, the second interlayer insulating film 26 is formed as illustrated in FIG. 19. Subsequently, the first gate insulating film 23, the first interlayer insulating film 25, and the second interlayer insulating film 26 are patterned to form the first contact holes H1, the second contact holes H2, and the seventh contact hole H7.

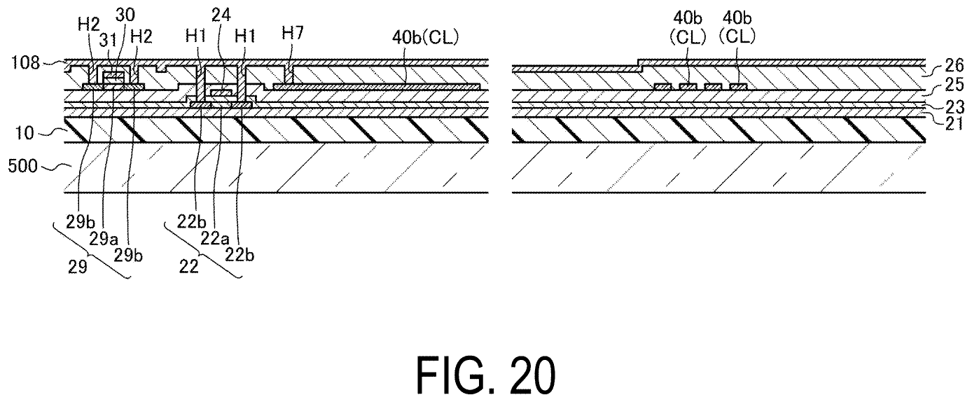

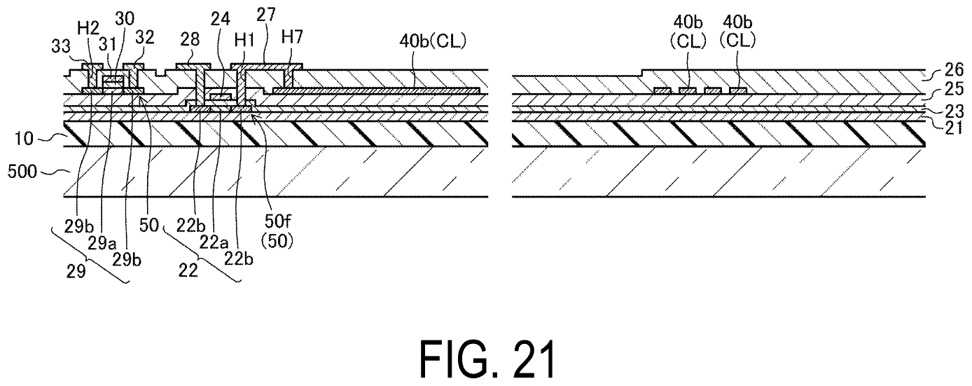

Next, on the substrate in which the first contact holes H1 and the like are formed, a titanium film, an aluminum film, and a titanium film are sequentially formed by, for example, a sputtering technique. By doing so, as illustrated in FIG. 20, a fourth metal film 108 is formed. Subsequently, the fourth metal film 108 is patterned to form the first, second, third and fourth terminal electrodes 27, 28, 32 and 33, and the like as illustrated in FIG. 21.

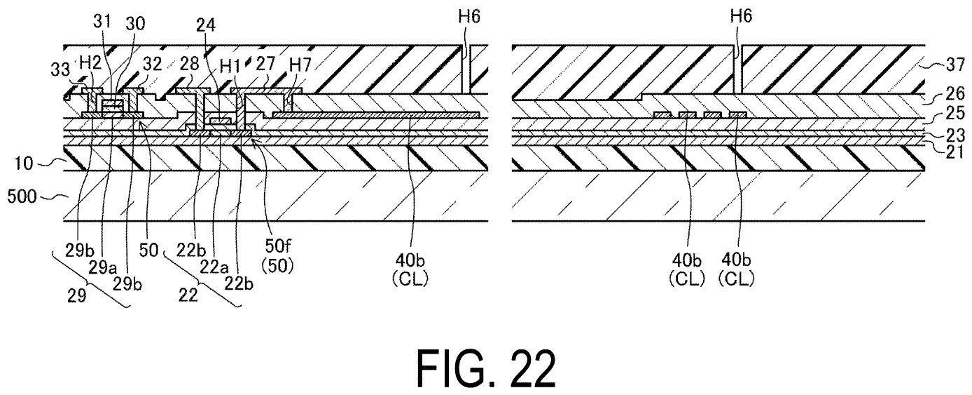

Further, on the substrate on which the first terminal electrode 27 and the like are formed, an acrylic photosensitive resin is applied by, for example, a spin coating method or a slit coating method. Subsequently, the applied resin film is pre-baked, exposed, developed, and post-baked to form the first flattening film 37 having the third contact holes H3 and the sixth contact holes H6 as illustrated in FIG. 22. Then, the second interlayer insulating film exposed at the bottom of the sixth contact hole of the first flattening film 37 is removed so that the sixth contact hole H6 reaches the second connection line 40b.

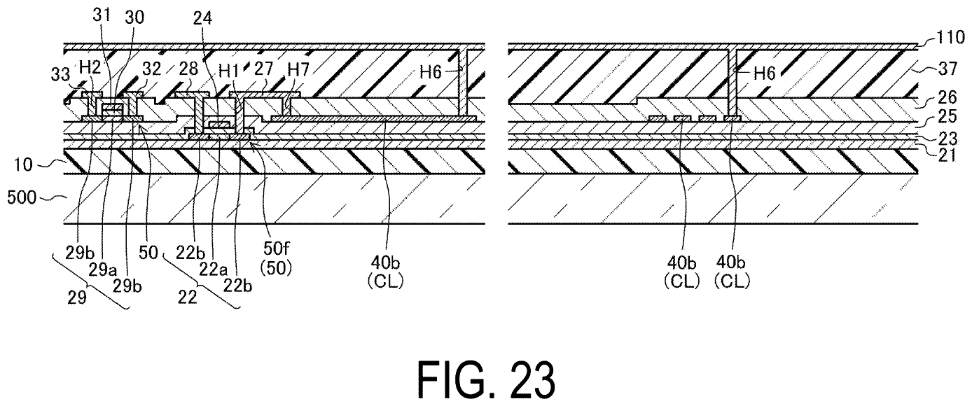

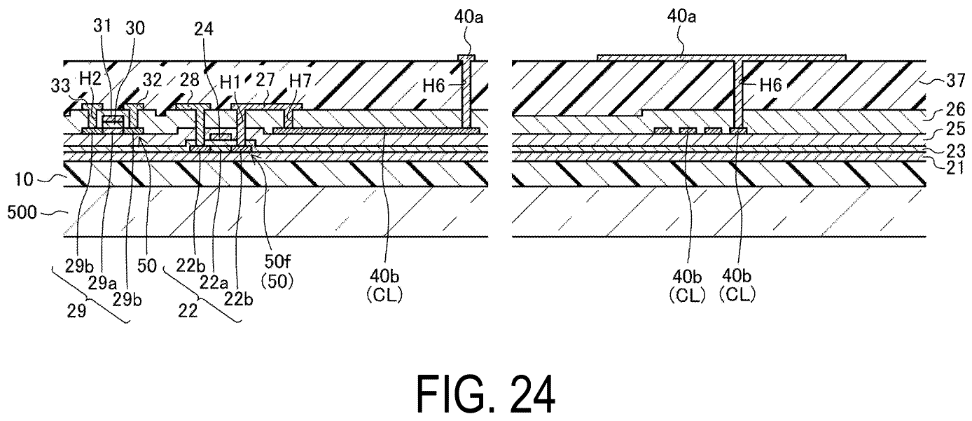

Next, as illustrated in FIG. 23, on the substrate on which the first flattening film 37 is formed, a third semiconductor film 110 made of an oxide semiconductor such as InGaZnO₄ is formed by, for example, a plasma CVD technique. In this case, as a film formation apparatus for forming the third semiconductor film 110, a film formation apparatus (CVD apparatus) common to the film formation of the second semiconductor film 102 may be used. Then, the third semiconductor film 110 is patterned to form the first connection lines 40a as illustrated in FIG. 24. At this time, the relay lines 40r are formed at the same time.

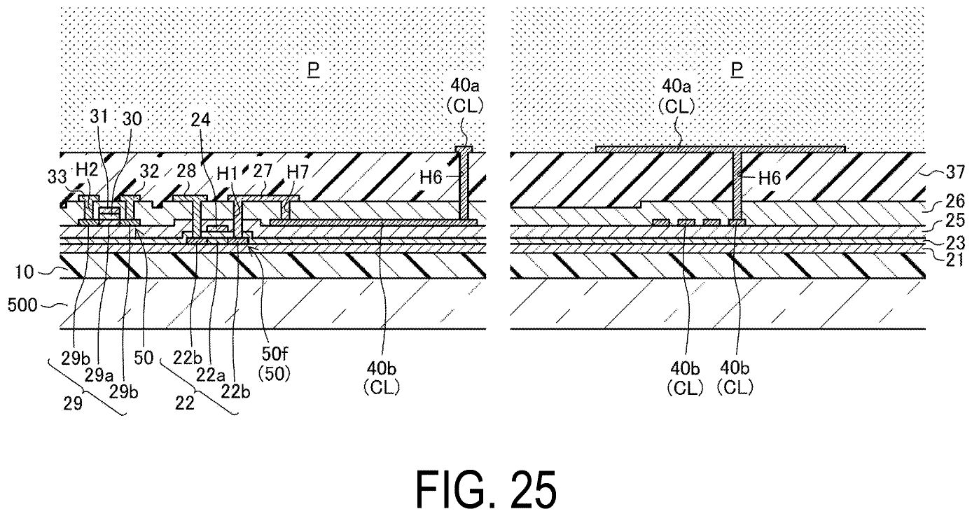

Then, as illustrated in FIG. 25, hydrogen plasma treatment is performed on the surface of the substrate on which the first connection lines 40a and the like are formed. When the oxide semiconductor forming the first connection line 40a and the relay line 40r is exposed to the plasma P, the resistance thereof is lowered due to the occurrence of oxygen deficiency. Thus, the first connection line 40a and the relay line 40r are each made to be a conductor.

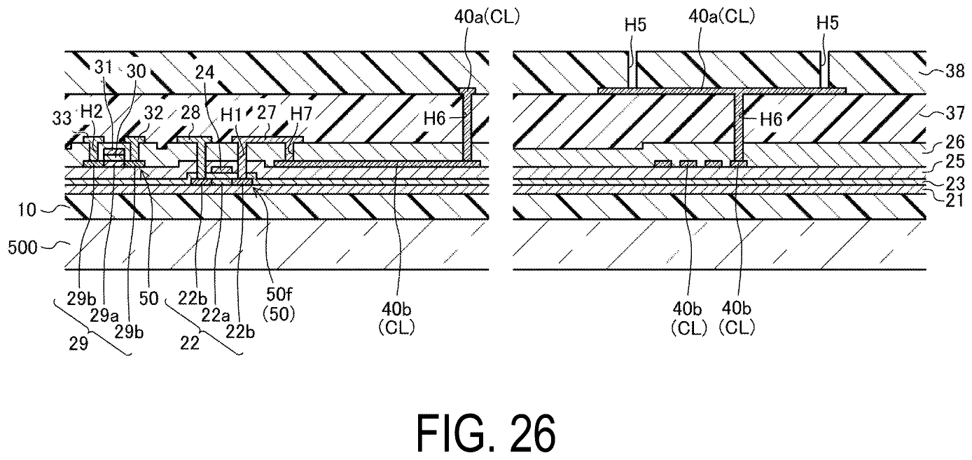

Next, on the substrate on which the first connection lines 40a and the like are formed, an acrylic photosensitive resin is applied by, for example, a spin coating method or a slit coating method. Subsequently, the applied resin film is pre-baked, exposed, developed, and post-baked to form the second flattening film 38 having the fourth contact holes H4 and the fifth contact holes H5 as illustrated in FIG. 26.

In the present embodiment, as a method for causing the oxide semiconductor forming the second semiconductor layer 29, the first connection line 40a, and the second connection line 40b to be a conductor, a technique that performs hydrogen plasma treatment is described as an example. However, the disclosure is not limited thereto, and any method that controls the carrier density of the oxide semiconductor may be employed. For example, a silicon nitride film or a silicon oxynitride film may be formed on a surface of a portion to be a conductor of a layer including an oxide semiconductor so as to increase the oxygen deficiency in the oxide semiconductor, whereby the oxide semiconductor may be made to be a conductor.

### Advantages of Embodiment

In the organic EL display device 1 of the present embodiment, each of the first connection line 40a and the second connection line 40b has optical transparency. This makes it possible to raise the transmittance of light in the second display region DA2. The first connection line 40a is formed in the same layer as the layer of the first semiconductor layer 22, and is constituted of the conductor layer CL obtained by converting an oxide semiconductor into a conductor. With this, the number of layers of the organic EL display device 1 can be reduced as compared with a case where the first semiconductor layer 22 and the second connection line 40b are formed as different layers. As a result, the manufacturing cost of the organic EL display device 1 can be reduced, and the transmittance of light in the second display region DA2 can be improved.

In the organic EL display device 1 of the present embodiment, the first connection line 40a is formed at the upper layer of the first flattening film 37, while the second connection line 40b is formed at the lower layer of the second interlayer insulating film 26. Thus, at the intersection of the first connection line 40a and the second connection line 40b, a relatively wide interval can be secured between these wiring lines 40a and 40b. Accordingly, it is possible to reduce parasitic capacitance between the first connection line 40a and the second connection line 40b and to improve a signal delay caused by the parasitic capacitance. In addition, by reducing the number of layers of the organic EL display device 1, it is possible to reduce the number of times of performing annealing treatment and improve the deterioration in TFT characteristics due to the thermal history. Furthermore, with the reduction in the number of layers of the organic EL display device 1, the risk of formation of a moisture entry path can be reduced, and the reliability of the organic EL display device 1 can be improved.

In the organic EL display device 1 of the present embodiment, the organic EL elements 70 forming the subpixels SP of the second display region DA2 are disposed in the light-emitting element region EA, and the plurality of pixel circuits PC for controlling the light emission of the organic EL elements 70 in the light-emitting element region EA are disposed around the light-emitting element region EA. According to this configuration, it is unnecessary to provide the pixel circuit PC in the light-emitting element region EA. Thus, in the light-emitting element region EA, light from the front face side of the display region DA is suitably transmitted to the back face side, thereby making it possible to secure external light received by the camera 3. This is advantageous for the camera 3 to exhibit the imaging function.

In the organic EL display device 1 of the present embodiment, in the second display region DA2, the first metal lines 40X and the second metal lines 40Y respectively extend via the outer side of the group of the organic EL elements 70 disposed in the light-emitting element region EA. According to this configuration, it is possible to reduce a situation in which the transmission of light from the front face side to the back face side of the light-emitting element region EA is blocked by the first metal lines 40X and the second metal lines 40Y. This is advantageous for securing external light received by the camera 3.

In the organic EL display device 1 of the present embodiment, the first connection line 40a and the second connection line 40b are each constituted of the conductor layer CL obtained by converting the same type of oxide semiconductor into a conductor. With this configuration, it is unnecessary to prepare a film formation apparatus for forming the first connection line 40a separately from a film formation apparatus for forming the second connection line 40b.

### Modified Example

In the organic EL display device 1 of the present example, the first connection line 40a and the relay line 40r are each made of transparent conductive oxide (TCO) having higher transmittance of light than that of the oxide semiconductor having been made to be a conductor and constituting the second connection line. Examples of the transparent conductive oxide constituting the first connection line 40a and the relay line 40r include indium tin oxide (ITO), indium zinc oxide (IZO), tin oxide (SnO), and zinc oxide (ZnO).

In the organic EL display device 1 of the present example, the first connection line 40a and the relay line 40r are each made of transparent conductive oxide and have higher transmittance of light than that of the oxide semiconductor having been made to be a conductor and constituting the second connection line 40b. This makes it possible to further raise the transmittance of light in the second display region DA2. This is advantageous for securing external light received by the camera 3.

### Other Embodiments

In the above-described embodiment, two organic EL elements 70 of the plurality of organic EL elements 70 provided in the light-emitting element region EA form one set, and the organic EL elements 70 in each set are connected to each other via the first connection line 40a, but the disclosure is not limited thereto. Three or more organic EL elements 70 of the plurality of organic EL elements 70 in the light-emitting element region EA may form one set, and the organic EL elements 70 in each set may be connected to each other via the first connection line 40a.

Two or more organic EL elements 70 of the plurality of organic EL elements 70 provided in the light-emitting element region EA may be allowed not to form one set. That is, the plurality of organic EL elements 70 in the light-emitting element region EA may be allowed not to be connected to each other and may be individually controlled. In this case, in the circuit disposition region CA, a separate pixel circuit PC is provided for each organic EL element 70, and each organic EL element 70 is connected to each separate pixel circuit PC via the first connection line 40a and the second connection line 40b.

In the above-described embodiment, the plurality of TFTs 50 provided for each subpixel SP include the polysilicon TFT 50P and the oxide semiconductor TFT 50Q, but the disclosure is not limited thereto. The plurality of TFTs 50 may include only the oxide semiconductor TFT 50Q. In other words, the TFTs 50 constituting the pixel circuit PC (the initialization TFT 50a, compensation TFT 50b, writing TFT 50c, drive TFT 50d, power supply TFT 50e, light emission control TFT 50f, and anode electrode discharge TFT 50g) may all be constituted of the oxide semiconductor TFTs 50Q.

In the above embodiment, the organic EL layer 62 is provided individually in each of the subpixels SP, but no such limitation is intended. The organic EL layer 62 may be continuously provided to be common in the plurality of subpixels SP. In this case, the organic EL display device 1 may include a color filter, for example, to perform color tone expression of each of the subpixels SP.

In the above embodiment, each of the pixels PX is constituted by the subpixels SP of three colors, but no such limitation is intended. The subpixels SP constituting each pixel PX may have four or more colors. The subpixels SP of three colors constituting each pixel PX are provided in a stripe array, but no such limitation is intended. The array of the plurality of subpixels PS may be another array such as PenTile arrangement.

In the above embodiment, the number of pieces of the plurality of TFTs 50 constituting the pixel circuit PC is seven, where there are included the initialization TFT 50a, compensation TFT 50b, writing TFT 50c, drive TFT 50d, power supply TFT 50e, light emission control TFT 50f, and anode electrode discharge TFT 50g, but the disclosure is not limited thereto; the number of pieces of the plurality of TFTs 50 constituting the pixel circuit PC may be six or more, or may be eight or more. In addition, each TFT 50 may be configured as a bottom gate type.

In the above embodiment, the organic EL element 70 is configured as a top-emitting type, but no such limitation is intended. The organic EL element 70 may be configured as a bottom-emitting type in which light emitted in the organic EL layer 62 is extracted from a substrate layer 10 side. The organic EL element 70 may be configured as a double-sided light-emitting type in which light emitted in the organic EL layer 62 is extracted from both the substrate layer 10 side and the sealing film 80 side.

In the above embodiment, the pixel electrode 61 is an anode electrode, and the common electrode 63 is a cathode electrode, but no such limitation is intended. The organic EL display device 1 may be configured such that the pixel electrode 61 functions as a cathode electrode and the common electrode 63 functions as an anode electrode. In this case, the organic EL layer 62 has an inverted layered structure.

In the embodiment discussed above, the organic EL layer 62 has a five-layer structure including the hole injection layer, the hole transport layer, the light-emitting layer, the electron transport layer, and the electron injection layer, but no such limitation is intended. The organic EL layer 62 may have a three-layer structure including a hole injection layer and hole transport layer, a light-emitting layer, and an electron transport layer and electron injection layer, and may employ any layered structure.

In the embodiment discussed above, as an electronic component that can be combined with the organic EL display device 1, the camera 3 is exemplified, but the disclosure is not limited thereto. The electronic component mentioned above may be another electronic component such as a fingerprint sensor, a face recognition sensor, or a luminance sensor as long as the electronic component is disposed at a position overlapping the second display region DA2 on the back face side of the organic EL display device 1, and configured to utilize the light transmitted through the display region DA.

In the above embodiment, the organic EL display device 1 has been exemplified as the display device according to the disclosure, but no such limitation is intended. The technique of the disclosure can be applied to a display device provided with a plurality of light-emitting elements to be driven by a current. Examples of the display device include a display device including a Quantum-dot light emitting diode (QLED), which is a light-emitting element using a quantum dot-containing layer.

As described above, the preferred embodiments are described as examples of the technique of the disclosure. However, the technique of the disclosure is not limited to the embodiments and the modified examples, and is also applicable to an embodiment in which modification, replacement, adding, omission, and the like are suitably made. It is understood by those skilled in the art that various modified examples can be made to the above embodiment without departing from the spirit of the technology of the disclosure, and such modified examples also belong to the scope of the technology of the disclosure.

### Industrial Applicability

As described above, the technique of the disclosure is useful for a display device.

### REFERENCE SIGNS LIST

CL Conductor layer
DA Display region
DA1 First display region
DA2 Second display region
EA Light-emitting element region
PC Pixel circuit
X First direction
Y Second direction
1 Organic EL display device (display device)
3 Camera (electronic component)
10 Substrate layer (substrate)
20 TFT layer (thin film transistor layer)
22 First semiconductor layer
29 Second semiconductor layer
40a First connection line
40b Second connection line
40e Light emission control line (first metal line)
40g Gate line (first metal line)
40i Second initialization line (first metal line)
40p Power source line (second metal line)
40s Source line (second metal line)
40X First metal line
40Y Second metal line
50 TFT (thin film transistor)
50P Polysilicon TFT (second thin film transistor)
50Q Oxide semiconductor TFT (first thin film transistor)
60 Light-emitting element layer
70 Organic EL element (light-emitting element)

1. A display device comprising:
a substrate;
a thin film transistor layer provided on the substrate; and
a light-emitting element layer provided on the thin film transistor layer, the thin film transistor layer including a plurality of thin film transistors, the light-emitting element layer including a plurality of light-emitting elements corresponding to a plurality of subpixels forming a display region, an electronic component configured to utilize light being disposed on a back face side of the substrate at a position overlapping the display region in a plan view,
wherein the display region includes a first display region and a second display region that is provided inside the first display region and transmits light to be utilized by the electronic component,
the plurality of thin film transistors include a first thin film transistor including a semiconductor layer formed of an oxide semiconductor,
in the second display region, a plurality of first connection lines electrically connected to the plurality of light-emitting elements and a plurality of second connection lines electrically connecting the plurality of first connection lines and the plurality of thin film transistors are provided,
the first connection line and the second connection line have optical transparency and are formed in different layers from each other, and
the second connection line is formed in a layer identical to the layer of the semiconductor layer of the first thin film transistor, and is constituted of a conductor layer obtained by converting the oxide semiconductor into a conductor.

2. The display device according to claim 1,
wherein the second display region includes a light-emitting element region in which the plurality of light-emitting elements are disposed, and
a pixel circuit that includes the thin film transistor and controls light emission of the light-emitting element disposed in the light-emitting element region is provided around the light-emitting element region.

3. The display device according to claim 2,
wherein the first connection line electrically connects the light-emitting elements adjacent to each other,
a plurality of sets of the light-emitting elements are disposed in the light-emitting element region, each set including two or more light-emitting elements connected to each other via the first connection line, and
the pixel circuit is provided for each set of the light-emitting elements and controls light emission of the two or more light-emitting elements forming each set in common.

4. The display device according to claim 2,
wherein a plurality of first metal lines made of a metal material extend parallel to each other in a first direction in the display region, and
the plurality of first metal lines extend via an outer side of a group of the light-emitting elements disposed in the light-emitting element region.

5. The display device according to claim 4,
wherein a plurality of second metal lines made of a metal material extend parallel to each other in a second direction orthogonal to the first direction in the display region, and
the plurality of second metal lines extend via the outer side of the group of the light-emitting elements disposed in the light-emitting element region.

6. The display device according to claim 1,
wherein the oxide semiconductor includes at least one semiconductor selected from the group consisting of an In—Ga—Zn—O based semiconductor, an In—Sn—Zn—O based semiconductor, an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, an Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, and an In—Ga—Zn—Sn—O based semiconductor.

7. The display device according to claim 1,
wherein the first connection line is constituted of a conductor layer in which an oxide semiconductor of a type identical to the type of the second connection line is converted into a conductor.

8. The display device according to claim 1,
wherein the first connection line is constituted of a transparent conductive oxide having higher transmittance of light than the conductive oxide semiconductor having been made to be a conductor and constituting the second connection line.

9. The display device according to claim 1,
wherein the plurality of thin film transistors include a second thin film transistor including a semiconductor layer formed of polysilicon, and
the first thin film transistor and the second thin film transistor constitute a pixel circuit configured to control light emission of the light-emitting element.

10. The display device according to claim 1,
wherein the electronic component is a camera.

11. The display device according to claim 1,
wherein the light-emitting element is an organic electroluminescence element.
